(19) United States
(12) Patent Application Publication
(10) Pub. No.: US 2004/0149212 A1
(43) Pub. Date: Aug. 5, 2004

(54) Reaction chamber for depositing thin film

(76) Inventors: Byung Chul Cho, Pyungtaek-city (KR); Keun Jae Yoo, Pyungtaek-city (KR); Hong Joo Lim, Pyungtaek-city (KR); Jang Ho Bae, Pyungtaek-city (KR); Sang Kyu Lee, Pyungtaek-city (KR); Hyun Soo Kyung, Pyungtaek-city (KR)

Correspondence Address: CANTOR COLBURN, LLP, 55 GRIFFIN ROAD SOUTH, BLOOMFIELD, CT, 06002

(21) Appl. No.: 10/748,098

(22) Filed: Dec. 30, 2003

(30) Foreign Application Priority Data
Jan. 3, 2003 (KR) 2003-365

(51) Int. Cl. C23C 16/00

(52) U.S. Cl. 118/715

(57) ABSTRACT

Provided is a reaction chamber for depositing a thin film. The reaction chamber includes a reactor block; a wafer block located inside the reactor block; a top plate that covers the reactor block to maintain a predetermined pressure; a feeding unit which supplies reactive gases to the reactor block; a shower head, which is installed in the top plate and includes a plurality of first spray holes for spraying the first reactive gas on a wafer and a plurality of second spray holes for spraying the second reactive gas; and an exhaust unit which expels gases from the reactor block. The feeding unit includes a feeding block; a distributing block; two or more first gas transfer pipes; and a second gas transfer pipe. The shower head includes an upper diffusion block, an intermediate diffusion block, and a lower diffusion block.

This application claims the priority of Korean Patent Application No. 2003-00365, filed on Jan. 3, 2003, in the Korean Intellectual Property Office, the disclosure of which is incorporated herein in its entirety by reference.

### BACKGROUND OF THE INVENTION

1. Field of the Invention

The present invention relates to a reaction chamber for depositing a thin film on a wafer.

2. Description of the Related Art

A reaction chamber for depositing a thin film on a wafer is an apparatus into which a variety of reactive gases are sprayed to deposit a predetermined thin film on a wafer. In order to manufacture a highly integrated chip, the thin film deposited on the wafer should have few impurities and exhibit excellent electric characteristics. Also, as research and development of semiconductor manufacturers are aimed at reducing the design rule, a thin film should be deposited uniformly on a wafer. To form a uniform thin film, reactive gases should be uniformly sprayed on a wafer in a reaction chamber. Therefore, research has progressed to develop reaction chambers with improved structures.

### SUMMARY OF THE INVENTION

The present invention provides a reaction chamber for depositing a thin film, in which a thin film can be deposited on a wafer using a plurality of reactive gases such that the thin film contains few impurities and exhibits excellent electric characteristics.

The present invention also provides a reaction chamber for depositing a thin film, which allows reactive gases to be uniformly sprayed on a wafer.

In accordance with an aspect of the present invention, there is provided a reaction chamber for depositing a thin film. The reaction chamber comprises a reactor block; a wafer block located in the reactor block, a top plate that covers the reactor block to maintain a predetermined pressure, a feeding unit which supplies a first reactive gas and a second reactive gas, a shower head, which is installed in the top plate and includes a plurality of first spray holes for spraying the first reactive gas on a wafer and a plurality of second spray holes for spraying the second reactive gas on the wafer, and an exhaust unit which expels the remaining gases from the reactor block.

The feeding unit may comprise a feeding block which is connected to the shower head, a distributing block which is connected to a first gas supply line to uniformly distribute the first reactive gas, two or more first gas transfer pipes which connect the feeding block with the distributing block, and a second gas transfer pipe which is formed in the center of the feeding block and connected to the second gas supply line.

The shower head may comprise an upper diffusion block connected to the bottom of the feeding unit, an intermediate diffusion block adhered to the bottom of the intermediate diffusion block, and a lower diffusion block adhered to the bottom of the intermediate diffusion block.

The upper diffusion block may comprise a connecting unit which is connected to the feeding block and includes first feeding holes which are respectively connected to the first gas transfer pipes and a second feeding hole which is connected to the second gas transfer pipe, a plurality of first main flow paths and a plurality of first sub-flow paths, which are formed on the bottom of the connecting unit. The first main flow paths may be respectively connected to the first feeding holes and be radially and symmetrically formed around the center of the connecting unit, and the first sub-flow paths may extend perpendicularly from each of the first main flow paths.

The intermediate diffusion block may comprise second main flow paths and second sub-flow paths, which are formed on the intermediate diffusion block and correspond to the first main flow paths and the first sub-flow paths, respectively, a plurality of first distributing holes, which are formed in the second sub-flow paths and second main flow paths at regular intervals, and a second distributing hole which is connected to the second feeding hole.

The lower diffusion block may comprise a plurality of first spray holes which are connected to the first distributing holes, respectively, and for spraying the first reactive gas on the wafer and a plurality of second spray holes formed between the first spray holes and for spraying the second reactive gas on the wafer.

The first gas transfer pipes may be symmetrically disposed between the feeding block and the distributing block.

A diffusion region having roughness ( [symbol] [symbol] ) may be formed on the top surface of the lower diffusion block. The first spray holes may be formed in convex portions ( [symbol] ), and the second spray holes may be formed in concave portions ( [symbol] ).

A temperature sensor and a heater may be mounted on the feeding block.

Each of the first sub-flow paths of the upper diffusion block may have the same shape as each of the second sub-flow paths of the intermediate diffusion block. Each of the first main flow paths of the upper diffusion block may have the same shape as each of the second main flow paths of the intermediate diffusion block.

The number of the first feeding holes may be proportional to each of the number of the first main flow paths and the number of the second main flow paths.

The upper diffusion block, the intermediate diffusion block, and the lower diffusion block may be integrally formed.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional view of a reaction chamber for depositing a thin film according to the present invention;

FIG. 2 is a partial top perspective view of a top plate and a shower head shown in FIG. 1;

FIG. 3 is a partial bottom perspective view of the top plate and the shower head shown in FIG. 1;

FIG. 4 is a perspective view of a feeding unit shown in FIG. 1;

FIG. 5 illustrates the bottom of an upper diffusion block shown in FIGS. 2 and 3;

FIG. 6 illustrates the top of an intermediate diffusion block shown in FIGS. 2 and 3;

FIG. 7 illustrates the bottom of the intermediate diffusion block shown in FIGS. 2 and 3;

FIG. 8 illustrates the top of a lower diffusion block shown in FIGS. 2 and 3;

FIG. 9 illustrates the bottom of the lower diffusion block shown in FIGS. 2 and 3;

FIGS. 10 through 13 illustrate possible patterns of first main flow paths, second main flow paths, first sub-flow paths, and second sub-flow paths.

### DETAILED DESCRIPTION OF THE INVENTION

Hereinafter, a reaction chamber for depositing a thin film according to the present invention will now be described more fully with reference to the accompanying drawings, in which exemplary embodiments of the invention are shown.

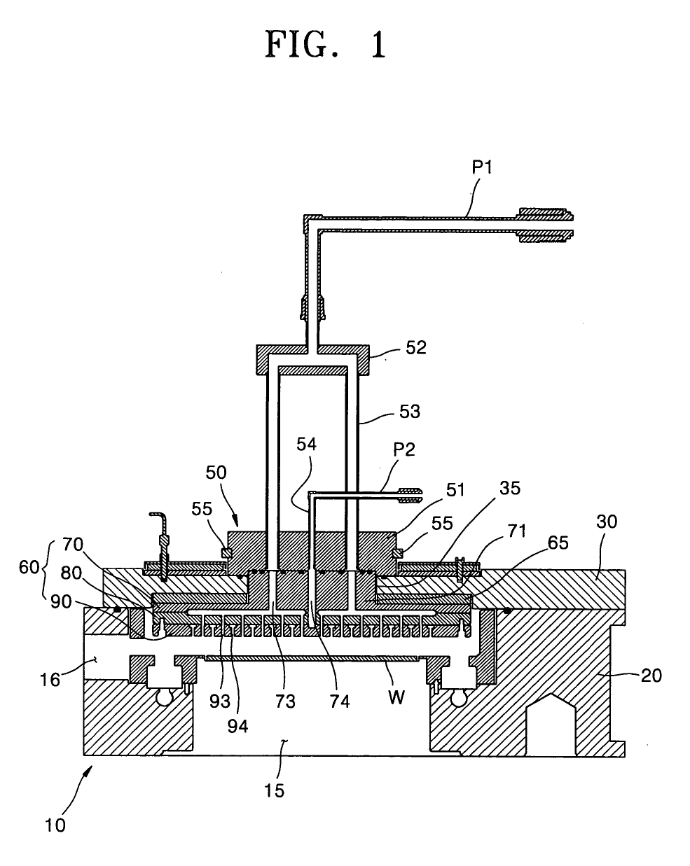

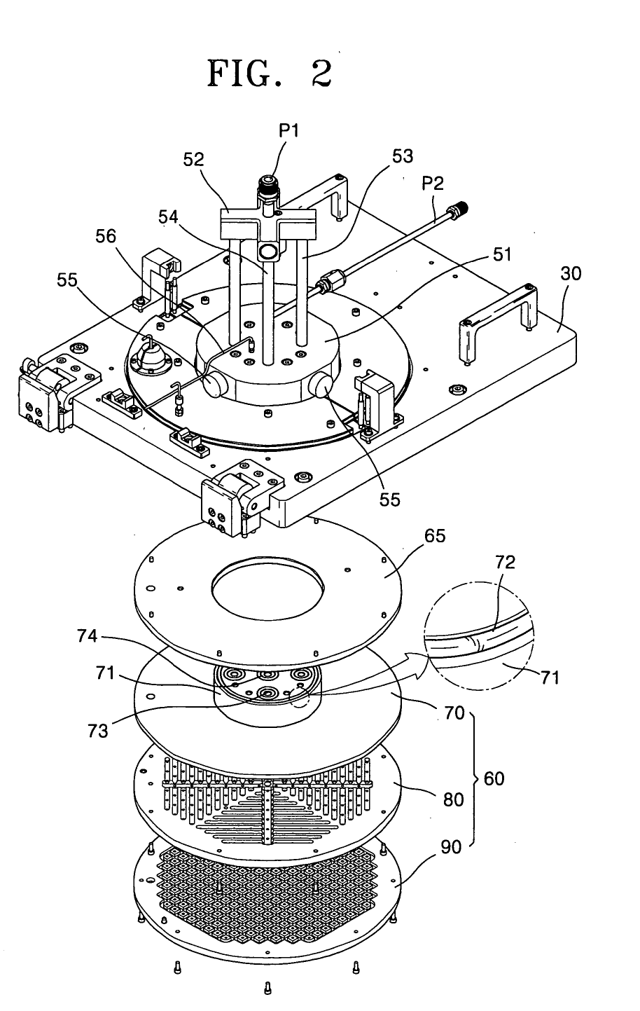

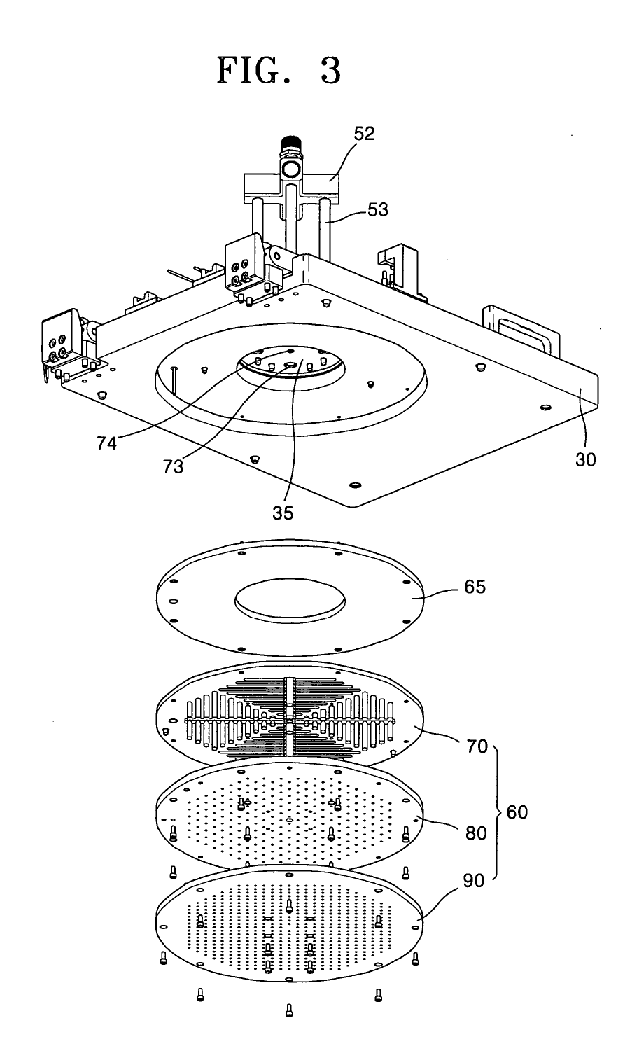

FIG. 1 is a cross-sectional view of a reaction chamber for depositing a thin film according to the present invention. FIGS. 2 and 3 are a partial top perspective view and a partial bottom perspective view, respectively, of a top plate and a shower head shown in FIG. 1. Referring to FIGS. 1, 2, and 3, a reaction chamber 10 comprises a reactor block 20, which includes a wafer block 15 on which a wafer W is mounted, and a top plate 30 that covers the reactor block 20 to maintain a predetermined pressure in the reaction chamber 10. A feeding unit 50 supplies a first reactive gas and a second reactive gas to a shower head 60, which includes a plurality of first spray holes 93 for spraying the first reactive gas on the wafer W and a plurality of second spray holes 94 for spraying the second reactive gas on the wafer W. An exhaust unit (not shown) expels the remaining gases from the reactor block 20. Since the reaction chamber 10 can comprise a conventional reactor block 20, top plate 30, and exhaust unit, a detailed description thereof will be omitted.

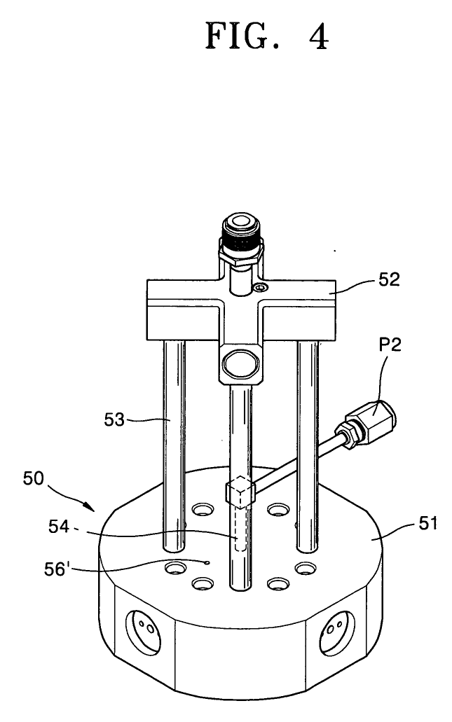

FIG. 4 is a partial perspective view of the feeding unit 50 shown in FIG. 1. Referring to FIG. 4, the feeding unit 50 comprises a feeding block 51, which is connected to the shower head 60 by a mounting hole 35 of the top plate 30 and a distributing block 52 that distributes the first reactive gas, which is supplied through a first gas supply line P1. Two or more first gas transfer pipes 53 connect the feeding block 51 with the distributing block 52. A second gas transfer pipe 54 is installed in the center of the feeding block 51 and connected to second gas supply lines P2. The first gas transfer pipes 53 transfer the first reactive gas from the distributing block 52 to the feeding block 51 and are symmetrically installed between the feeding block 51 and the distributing block 52. In the present invention, there are four first gas transfer pipes 53. A plurality of heaters 55 are installed on a lateral surface of the feeding block 51, and a temperature sensor 56 is mounted in a temperature sensor mounting hole 56′, formed in an upper portion of the feeding block 51. The heaters 55 and the temperature sensor 51 are mounted on the feeding block 51 to control the temperature of the reactive gas.

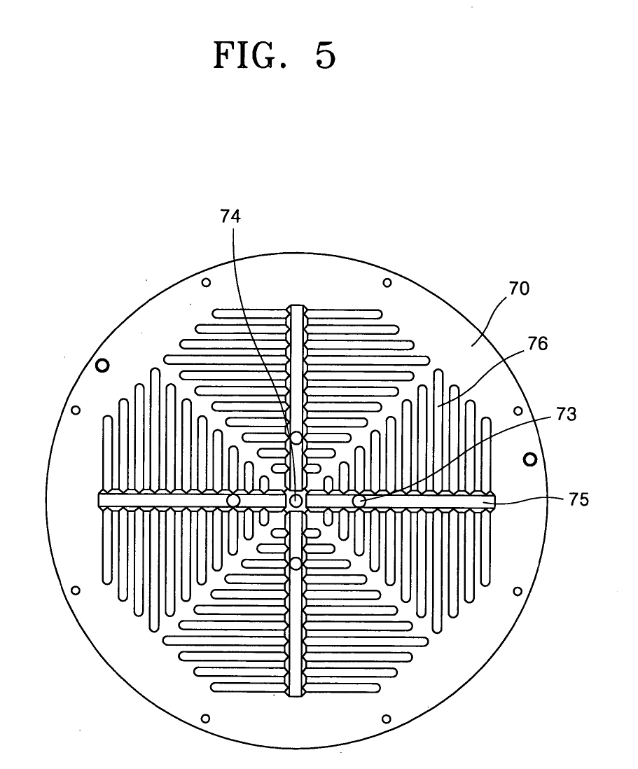

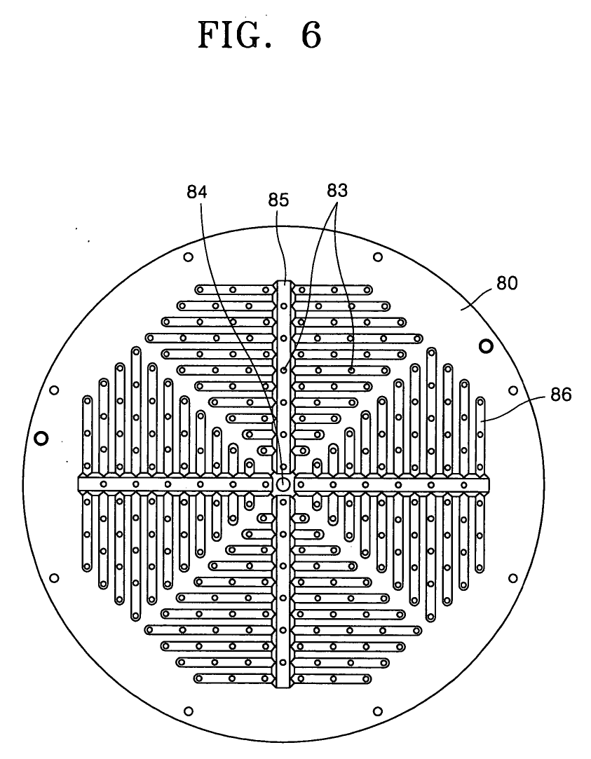

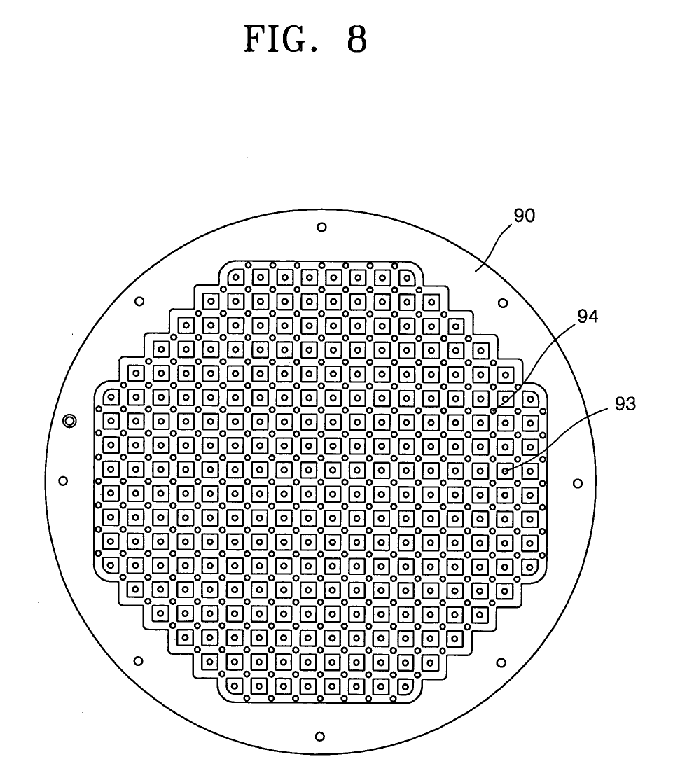

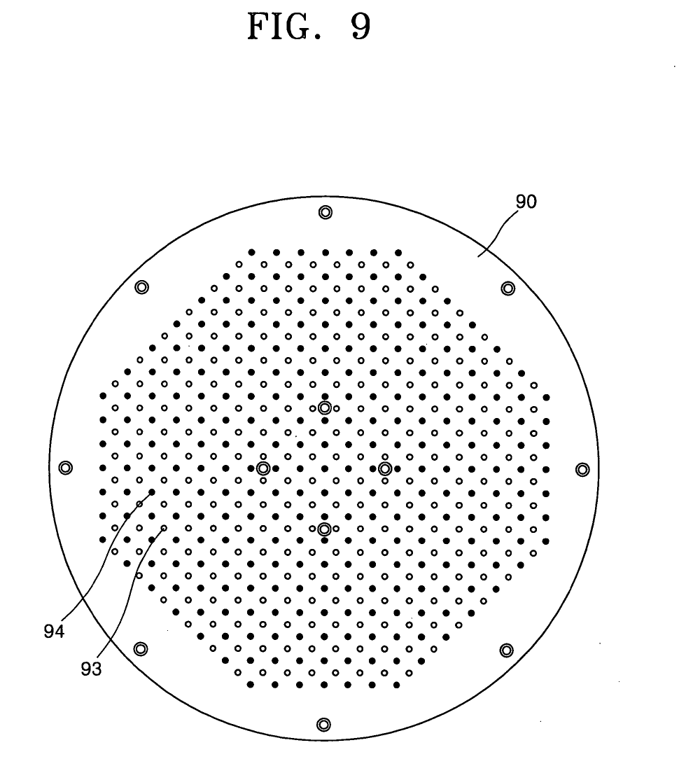

FIG. 5 illustrates the bottom of an upper diffusion block of FIGS. 2 and 3, FIG. 6 illustrates the top of an intermediate diffusion block of FIGS. 2 and 3, and FIG. 7 illustrates the bottom of the intermediate diffusion block of FIGS. 2 and 3. Also, FIG. 8 illustrates the top of a lower diffusion block of FIGS. 2 and 3, and FIG. 9 illustrates the bottom of the lower diffusion block of FIGS. 2 and 3.

Referring to FIGS. 5 through 9, the shower head 60 comprises an upper diffusion block 70, an intermediate diffusion block 80, and a lower diffusion block 90, which are sequentially connected to the bottom of the feeding unit 50. An adhesion support ring 65 may be further installed between the shower head 60 and the top plate 30 to tightly adhere the shower head 60 to the top plate 30.

Referring to FIG. 2, the upper diffusion block 70 comprises a connecting unit 71 that is formed on the top surface of the upper diffusion block 70 and connected to the feeding block 51. The connecting unit 71 includes first feeding holes 73 that are respectively connected to the first gas transfer pipes 53 and a second feeding hole 74 that is connected to the second gas transfer pipe 54. An O-ring glove (not shown) may be formed in the connecting unit that is connected to the feeding block 51. An O-ring 72 may be put in the O-ring glove and sealed tightly.

A plurality of first main flow paths 75 and a plurality of first sub-flow paths 76 are formed in the bottom of the upper diffusion block 70. The first main flow paths 75 are respectively connected to the first feeding holes 73 and are radially and symmetrically formed around the center of the upper diffusio block 70. The first sub-flow paths 76 extend perpendicularly from each of the first main flow paths 75.

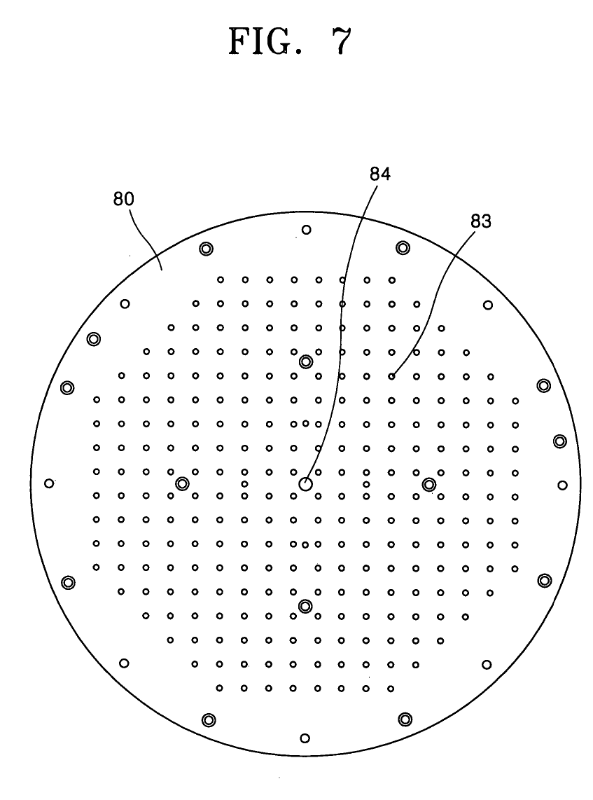

The intermediate diffusion block 80 is adhered to the bottom of the upper diffusion block 70. A plurality of second main flow paths 85 and a plurality of second sub-flow paths 86 are formed in the top surface of the intermediate diffusion block 80. The second main flow paths 85 correspond to the first main flow paths 75, respectively, and the second sub-flow paths 86 correspond to the first sub-flow paths 76, respectively. A plurality of first distributing holes 83 are formed at regular intervals in the second main flow paths 85 and the second sub-flow paths 86. Also, a second distributing hole 84 is in contact with the second feeding hole 74. The first distributing holes 83 and the second distributing hole 84 penetrate the intermediate diffusion block 80 as shown in FIG. 7. The first main flow paths 75 and the first subs flow paths 76, which are formed in the bottom of the upper diffusion block 70, are respectively connected to the second main flow paths 85 and the second sub-flow paths 86, which are formed in the top surface of the intermediate diffusion block 80, to form flow paths.

The lower diffusion block 90 is adhered to the bottom of the intermediate diffusion block 80. A diffusion region may be formed on the lower diffusion block 90 to uniformly distribute the second reactive gas supplied through the second distributing hole 84. The diffusion region is rough, i.e., a plurality of convex portions ( [symbol] ) and a plurality of concave portions ( [symbol] ) are formed in the diffusion region. A plurality of second spray holes 94 are respectively formed in the concave portions ( [symbol] ) and used to spray the second reactive gas supplied from the second distributing hole 84 on the wafer W. Also, a plurality of first spray holes 93 are respectively formed in the convex portions ( [symbol] ) and respectively connected to the first distributing holes 83. That is, the first spray holes 93 penetrate the convex portions ( [symbol] ), and the second spray holes 94 penetrate the concave portions ( [symbol] ).

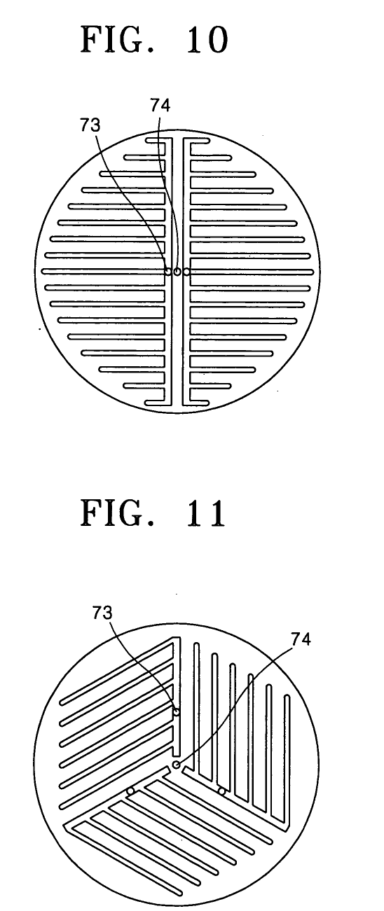

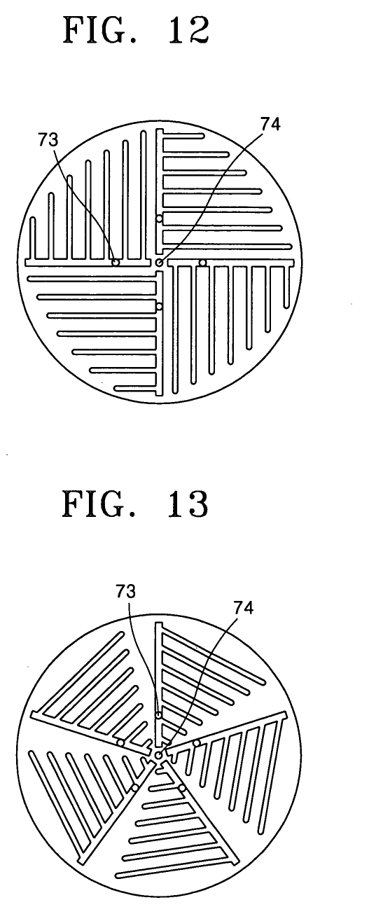

The number of the first main flow paths 75 and the number of the second main flow paths 85 each depend on the number of the first feeding holes 73. In the present invention, when there are four first feeding holes 73, there are four first main flow paths 75 and four second main flow paths 85. FIGS. 10 through 13 illustrate possible patterns of first main flow paths, second main flow paths, first sub-flow paths, and second sub-flow paths. Referring to FIG. 10, when there are two first feeding holes 73, there are two first main flow paths 75 and two second main flow paths 85. Referring to FIG. 11, when there are three first feeding holes 73, there are three first main flow paths 75 and three second main flow paths 85. Referring to FIG. 12, when there are fourth first feeding holes 73, there are four first main flow paths 75 and four second main flow paths 85. Referring to FIG. 13, when there are five first feeding holes 73, there are five first main flow paths 75 and five second main flow paths 85. Therefore, it can be seen that the number of the first main flow paths 75 and the number of the second main flow paths 85 are each proportional to the number of the first feeding holes 73. The first sub-flow paths 76 extend from the first main flow paths, and the second sub-flow paths 86 extend from the second main flow paths.

In the present invention, the upper diffusion block, the intermediate diffusion block, and the lower diffusion block are separately manufactured and integrally combined. However, the shower head 60 may comprise a single block instead.

Hereinafter, the operation of the reaction chamber for depositing a thin film according to the present invention will be described.

A wafer W is transferred through a wafer transfer hole 16 and mounted on the wafer block 15. Next, the wafer block 15 heats the wafer W to a predetermined temperature. While the wafer W is being heated to the predetermined temperature, the first reactive gas and/or an inert gas flow through the first gas supply line P1, the distributing block 52, the first gas transfer pipes 53, the first feeding holes 73, main flow paths including the first main flow paths 75 and the second main flow paths 85, sub-flow paths including the first sub-flow paths 76 and the second sub-flow paths 86, the first distributing holes 83 and the first spray holes 93, and is sprayed onto the wafer W.

Meanwhile, the second reactive gas and/or the inert gas flow through the second gas supply lines P2, the second feeding hole 74, and the second distributing hole 84, uniformly diffuse in the diffusion region, and is sprayed through the second spray holes 94 onto the wafer W.

The first reactive gas, the second reactive gas, and the inert gas generate a thin film on the wafer W, and gases that are obtained as by-products and not used for the deposition of the thin film are expelled through exhaust holes of the exhaust unit.

Thus, in the reaction chamber for depositing a thin film according to the present invention, a thin film can be uniformly deposited by spraying a plurality of reactive gases on a wafer such that the thin film has few impurities and exhibits excellent electric characteristics and step coverage characteristics.

What is claimed is:

1. A reaction chamber for depositing a thin film, the reaction chamber comprising: a reactor block; a wafer block located inside the reactor block; a top plate which covers the reactor block to maintain a predetermined pressure; a feeding unit which supplies a first reactive gas and a second reactive gas; a shower head, which is installed in the top plate and includes a plurality of first spray holes for spraying the first reactive gas supplied from the feeding unit on a wafer and a plurality of second spray holes for spraying the second reactive gas supplied from the feeding unit; and an exhaust unit which expels gases from the reactor block,
the feeding unit comprising:
a feeding block that is connected to the shower head;
a distributing block which is connected to a first gas supply line to uniformly distribute the first reactive gas;
two or more first gas transfer pipes which connect the feeding block to the distributing block; and
a second gas transfer pipe which is formed in the center of the feeding block and connected to the second gas supply line,
the shower head comprising an upper diffusion block connected to the bottom of the feeding unit, an intermediate diffusion block adhered to the bottom of the upper diffusion block, and a lower diffusion block adhered to the bottom of the intermediate diffusion block,
the upper diffusion block comprising:
a connecting unit which is connected to the feeding block and includes first feeding holes which are respectively connected to the first gas transfer pipes and a second feeding hole which is connected to the second gas transfer pipe;
a plurality of first main flow paths which are formed on the bottom of the connecting unit, which are connected to the first feeding holes, respectively, and are radially and symmetrically formed around the center of the connecting unit; and
a plurality of first sub-flow paths, which are formed in the bottom of the connecting unit and extend perpendicularly from each of the first main flow paths,
the intermediate diffusion block comprising:
a plurality of second main flow paths, which are formed on the intermediate diffusion block and respectively correspond to the first main flow paths;
a plurality of second sub-flow paths which are formed on the intermediate diffusion block and respectively correspond to the first sub-flow paths;
a plurality of first distributing holes which are formed at regular intervals in the second sub-flow paths and second main flow paths; and
a second distributing hole connected to the second feeding hole,
the lower diffusion block comprising:
a plurality of first spray holes connected to the first distributing holes, respectively, for spraying the first reactive gas on the wafer; and
a plurality of second spray holes formed between the first spray holes for spraying the second reactive gas on the wafer.

2. The reaction chamber of claim 1, wherein the first gas transfer pipes are symmetrically disposed between the feeding block and the distributing block.

3. The reaction chamber of claim 1, wherein a diffusion region having a plurality of convex portions and a plurality of concave portions is formed on the top surface of the lower diffusion block, and the first spray holes are formed in the convex portions and the second spray holes are formed in the concave portions.

4. The reaction chamber of claim 1, wherein a temperature sensor and a heater are mounted on the feeding block to control the temperature of the reactive gases.

5. The reaction chamber of claim 1, wherein each of the first sub-flow paths of the upper diffusion block has the same shape as each of the second sub-flow paths of the intermediate diffusion block, and each of the first main flow paths of the upper diffusion block has the same shape as each of the second main flow paths of the intermediate diffusion block.

6. The reaction chamber of claim 1, wherein the number of the first feeding holes is proportional to each of the number of the first main flow paths and the number of the second main flow paths.

7. The reaction chamber of claim 1, wherein the upper diffusion block, the intermediate diffusion block, and the lower diffusion block are integrally formed.
